(19) United States
(12) Patent Application Publication
(10) Pub. No.: US 2008/0149951 A1
(43) Pub. Date: Jun. 26, 2008

(54) Light emitting device

(75) Inventors: Ming-Te Lin, Hsinchu Hsien (TW); Hsi-Hsuan Yen, Hsinchu Hsien (TW); Ming-Yao Lin, Hsinchu Hsien (TW); Wen-Yung Yeh, Hsinchu Hsien (TW); Chia-Chang Kuo, Hsinchu Hsien (TW); Sheng-Pan Huang, Hsinchu Hsien (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/643,786

(22) Filed: Dec. 22, 2006

(51) Int. Cl. H01L 33/00; H01L 29/205

(52) U.S. Cl. 257/91

(57) ABSTRACT

A light emitting device including a carrying element having two electric conductors connectable to a power source, a light emitting element disposed on the carrying element and electrically connected to the two electric conductors, and at least one correction element electrically connected to the light emitting element, wherein the light emitting element is adapted to provide a light source upon connection of the two electric conductors with the power source, and the at least one correction element allows the light emitting element to have functions of temperature compensation, voltage correction, or surge absorption.

### BACKGROUND OF THE INVENTION

1. Field of the Invention

The present invention relates to light emitting devices, and more particularly, to a light emitting device characterized by temperature compensation, voltage correction, and surge absorption.

2. Description of the Prior Art

Lighting is indispensable to modern life and accounts for 40% of global electricity consumption. Based on optoelectronic technology, white light emitting diode (LED) bulbs are small-sized, energy-saving, durable and therefore likely to substitute for tungsten bulbs and mercury vapor bulbs in the twenty-first century to embody the notion of energy-saving, environment-friendly lighting. Over the past two decades, Taiwan ranks second behind Japan in terms of countries with the greatest LED business turnover.

An alternating current (AC) LED, for example, is composed of a plurality of light emitting microdies that number 30 to 100. The AC LED lights up and warms up as soon as it is connected to a power source. The increase in the temperature of the AC LED brings about a shift in the voltage-current characteristic curve of the AC LED. Referring to FIG. 1, L1 represents the voltage-current characteristic curve at temperature T1, and the voltage-current characteristic curve L1 shifts to a voltage-current characteristic curve L2 as soon as temperature increases to T2, which in turn results in voltage drop. Given a constant operating voltage, the operating power may even double. Furthermore, with a relatively low yield of the dies for AC LEDs, the power sources intended for the fabricated AC LEDs usually differ from one another, and in consequence light sources are seldom homogenous when operated under constant voltage. Lastly, instantaneous power supplied by a power source generates a pulse signal, which tends to burn AC LEDs.

Accordingly, an issue facing the optoelectronic industry and calling for urgent solution is to develop a light emitting diode characterized by temperature compensation, voltage correction, and surge absorption.

### SUMMARY OF THE INVENTION

In light of the aforesaid drawbacks of the prior art, it is a primary objective of the present invention to provide a light emitting device characterized by at least one of the functions of temperature compensation, voltage correction, and surge absorption.

In order to achieve the above and other objectives, the present invention provides a light emitting device comprising a carrying element having two electric conductors connectable to a power source, a light emitting element disposed on the carrying element and electrically connected to the two electric conductors, and at least one correction element electrically connected to the light emitting element.

In comparison with the prior art, the present invention discloses at least one correction element having at least one of the functions of temperature compensation, voltage correction, and surge absorption so as to achieve the primary objective and other objectives of the present invention.

### BRIEF DESCRIPTION OF THE DRAWINGS

FIG. 1 is a schematic view showing a shifting phenomenon of the voltage-current characteristic curve of a high-voltage light emitting diode;

FIG. 2 is a schematic view showing the structure of the first embodiment of a light emitting device in accordance with the present invention;

FIG. 3(A) is a schematic view showing the structure of the light emitting element of the first embodiment of a light emitting device in accordance with the present invention;

FIG. 3(B) is a schematic view showing an equivalent circuit of the light emitting element of the first embodiment of a light emitting device in accordance with the present invention;

FIG. 3(C) is a schematic view showing a first equivalent circuit of the series-connected light emitting element, alternating current light emitting diode, and correction element of a light emitting element in accordance with the present invention;

FIG. 3(D) is a schematic view showing a second equivalent circuit of the series-connected light emitting element, alternating current light emitting diode, and correction element of a light emitting element in accordance with the present invention;

FIG. 3(E) is a schematic view showing an equivalent circuit of the parallel-connected light emitting element and correction element of a light emitting element in accordance with the present invention;

FIG. 3(F) is a schematic view showing an equivalent circuit of the series-connected and parallel-connected light emitting element and correction element of a light emitting element in accordance with the present invention;

FIG. 4 is a schematic view showing a structure of the second embodiment of a light emitting device in accordance with the present invention;

FIG. 5(A) is a schematic view showing a structure of the electrically connected light emitting element and correction element of the second embodiment of a light emitting device in accordance with the present invention;

FIG. 5(B) is a schematic view showing an equivalent circuit of the electrically connected light emitting element and correction element of the second embodiment of a light emitting device in accordance with the present invention;

FIG. 6 is a schematic view showing a structure of the third embodiment of a light emitting device in accordance with the present invention;

FIGS. 7(A) and 7(B) are schematic views showing how to electrically connect a light emitting element, a correction element and a substrate of the third embodiment of a light emitting device in accordance with the present invention;

FIG. 7(C) is a schematic view showing an equivalent circuit of a light emitting element, a correction element and a substrate of the third embodiment of a light emitting device in accordance with the present invention;

FIG. 8 is a schematic view showing a structure of the fourth embodiment of a light emitting device in accordance with the present invention;

FIGS. 9(A) and 10(A) are schematic views showing how to electrically connect a light emitting element, a correction element and a substrate of the fourth embodiment of a light emitting device in accordance with the present invention; and

FIGS. 9(B) and 10(B) are schematic views showing equivalent circuits of a light emitting element, a correction element and a substrate of the fourth embodiment of a light emitting device in accordance with the present invention.

### DETAILED DESCRIPTION OF THE PREFERRED EMBODIMENTS

The following specific embodiments are provided to illustrate the present invention. Persons skilled in the art can readily gain an insight into other advantages and features of the present invention based on the contents disclosed in this specification.

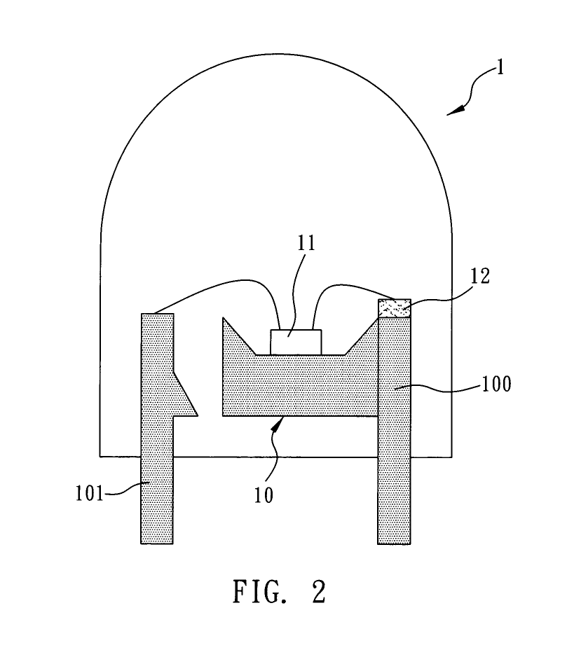

FIGS. 2, 3(A), 3(B), 3(C), 3(D), 3(E), 3(F), 4, 5(A), 5(B), 6, 7(A), 7(B), 7(C), 8, 9(A), 9(B), 10(A), and 10(B) are drawings about a light emitting device of the present invention. Points to note are as follows: all the accompanying drawings are simple schematic diagrams intended to schematically describe the basic structure of the present invention. Hence, in the drawings, only those components related to the present invention are shown, and the shown components are not drawn according to their actual quantity, shape and dimensions when implemented; in practice, the specifications and dimensions of the components are selectively devised indeed, and the layout of the components may be far more intricate.

Referring to FIG. 2, the first embodiment of a light emitting device 1 of the present invention comprises a carrying element 10, a light emitting element 11, and at least one correction element 12.

The carrying element 10 is disposed with two electric conductors 100 and 101 mountable with a power source. Preferably, the carrying element 10 is a carrier. The two electric conductors 100 and 101 together form a lead frame.

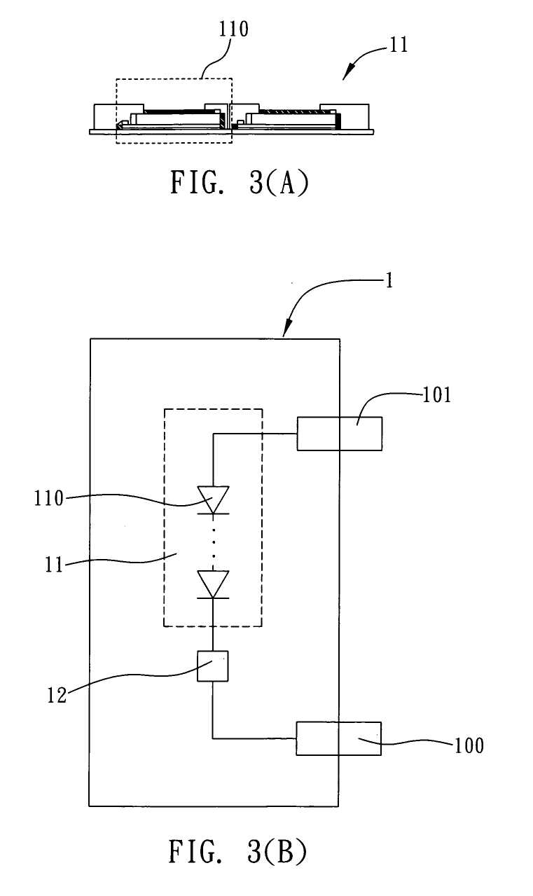

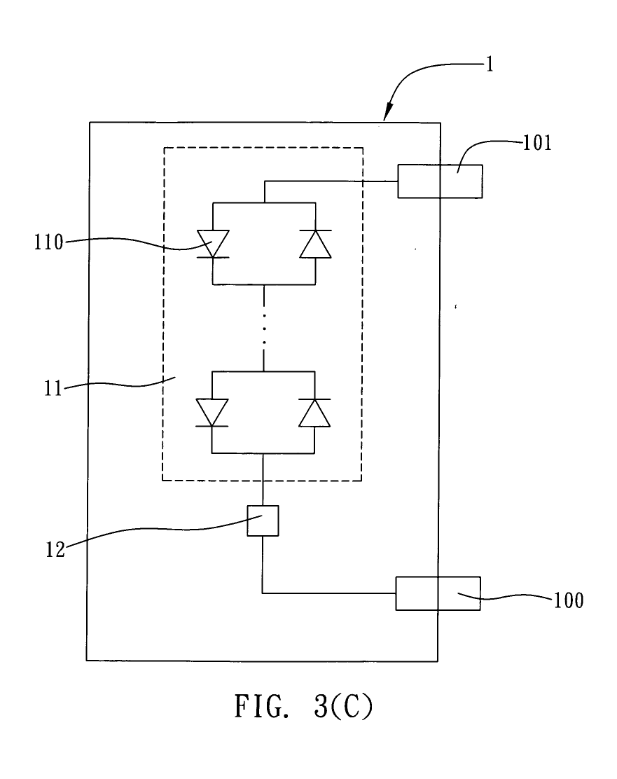

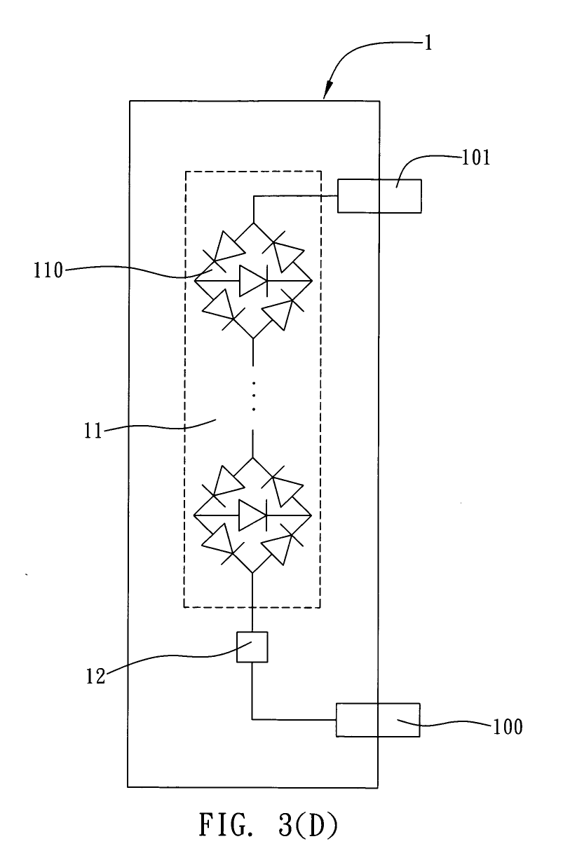

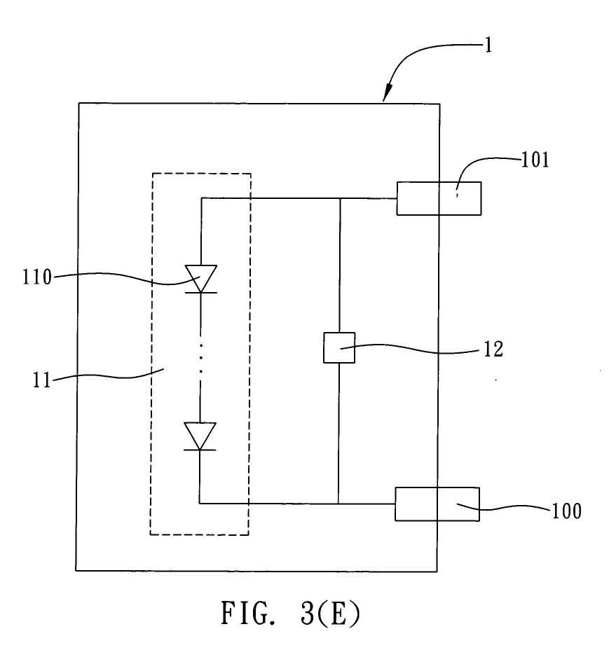

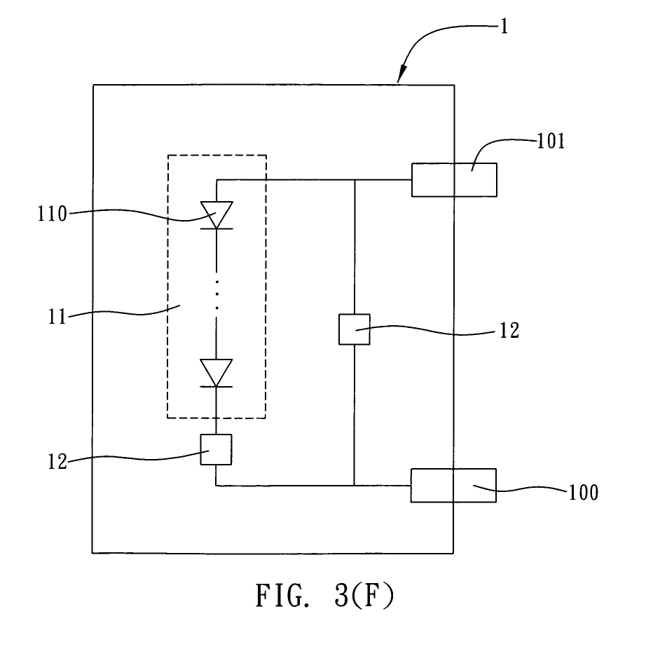

The light emitting element 111 is disposed on the carrying element 10, electrically connected to the two electric conductors 100 and 101, and adapted to provide a light source upon connection of the two electric conductors 100 and 101 with the power source. The light emitting element 11 comprises a plurality of alternating current light emitting diode (AC LED) dies or a plurality of direct current light emitting diode (DC LED) dies, as shown in FIG. 3(A) which illustrates an unidirectional DC LED die 110. In this embodiment, the unidirectional DC LED die 110 is a single-layered or double-layered light emitting element. The light emitting element 11 is operable at a single wavelength or at least two wavelengths. In other words, the light emitting element emits monochromic or polychromatic light. Upon connection to the power source, the light emitting element 11 provides the light source comprising visible light or invisible light (for example, ultraviolet light or infrared light).

The at least one correction element 12 is electrically connected to the light emitting element 11 and adapted to provide the light emitting element 11 with at least one of the functions of temperature compensation, voltage correction and surge absorption upon connection of the light emitting element 11 with the power source. As shown in FIG. 2, the at least one correction element 12 is electrically connected to the light emitting element 11 in a specific way that involves disposing the correction element 12 on the electric conductor 100 attaching to the carrying element 10. The light emitting element 11 is connected to the correction element 12 in series by wire bonding (as shown in the equivalent circuit of FIG. (3B)). Upon connection of the light emitting element 11 with the power source, the correction element 12 provides at least one function selected from the group consisting of temperature compensation, voltage correction, and surge absorption. Preferably, the correction element 12 is a temperature compensation element, a voltage correction element, a surge absorption element, or an element having at least two functions selected from the group consisting of temperature compensation, voltage correction, and surge absorption.

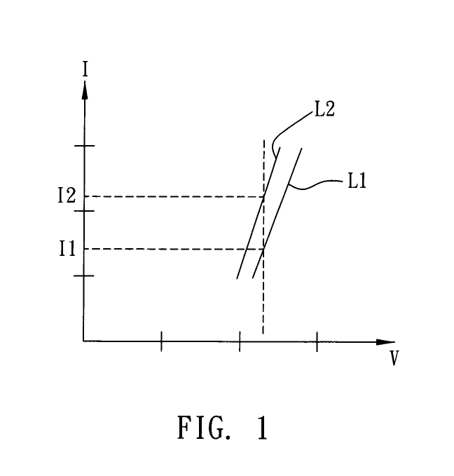

Referring to FIGS. 3(C) and 3(D), which show equivalent circuits of alternating current light emitting diode dies

Where the correction element 12 is a single temperature compensation element, the correction element 12 provides temperature compensation for the light emitting element 11. The sign of the temperature coefficient of a temperature compensation element depends on the need for compensation. Under constant voltage, an increase in the temperature of the light emitting element 11 brings about an increase of current (as shown in FIG. 1, current increases from I1 to I2) due to leftward shifting of the voltage-current characteristic curve, and thus an increase of impedance corrects the leftward shifting of the voltage-current characteristic curve when the light emitting element 11 is implemented as a positive temperature coefficient impedance compensation element. Alternatively, a decrease in the temperature of the light emitting element 11 brings about a decrease of current due to rightward shifting of the voltage-current characteristic curve, and thus a decrease of impedance corrects the rightward shifting of the voltage-current characteristic curve when the light emitting element 11 is implemented as a negative temperature coefficient impedance compensation element.

Where the correction element 12 is a voltage correction element, the correction element 12 provides voltage correction for the light emitting element 11. Voltage correction is intended to solve a problem—with a relatively low yield of the dies for the light emitting element 11, the power sources (that is, the driving biases for the light emitting element 11) usually differ from one another, and in consequence light sources are seldom homogenous when operated under constant voltage. The voltage correction element can be a resistor, a capacitor, an inductor, or any element capable of absorption of voltage drop.

Where the correction element 12 is a single surge absorption element, the correction element 12 provides surge absorption for the light emitting element 11. Surge absorption is intended to solve a problem—instantaneous power supplied by a power source generates a pulse signal, which tends to burn the light emitting element 11. In this regard, the light emitting element 11 and the correction element 12 are connected in parallel, thereby forming an equivalent circuit shown in FIG. 3(E). The surge absorption element can be a varistor, a capacitor, a Zener diode, or an element made of varistor material (for example, ZnO).

Where the correction element 12 is an element having at least two functions selected from the group consisting of temperature compensation, voltage correction, and surge absorption, the effect of the correction element 12 remains unchanged and therefore is not described herein again In this regard, the correction element 12 and the light emitting element 11 are connected in series and in parallel concurrently, as shown in FIG. 3(F).

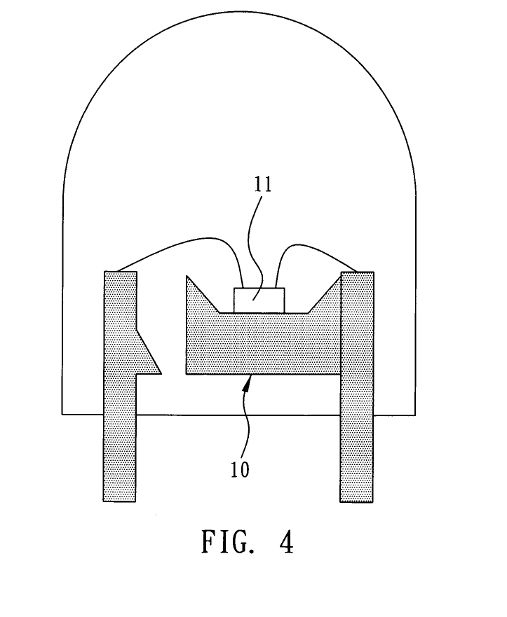

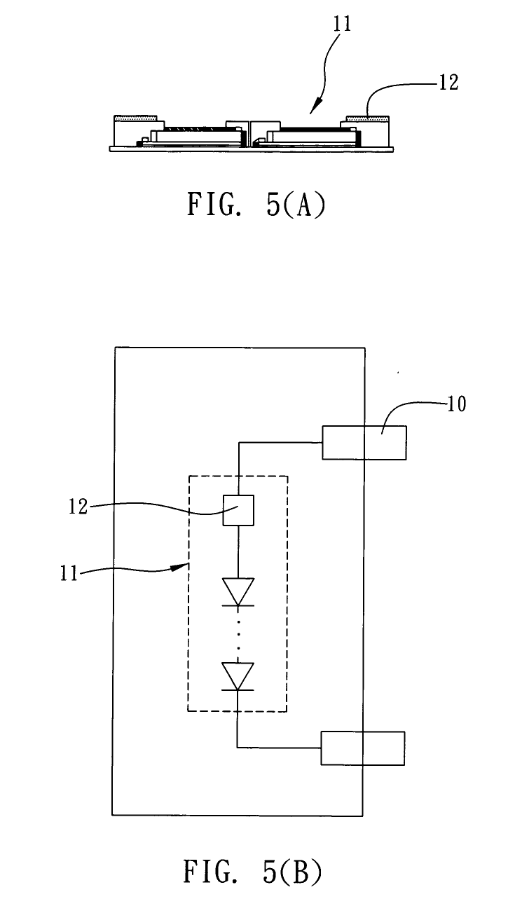

Referring to FIGS. 4 and 5(A), which are schematic views showing the structure of the second embodiment of a light emitting device of the present invention, the second embodiment is similar to the first embodiment in the way that not only does the light emitting device 1 comprise the carrying element 10, the light emitting element 11, and the at least one correction element 12, but the functions and implementation of the elements remain unchanged. Referring to FIG. 5(A), the second embodiment only differs from the first embodiment in electrical connection (referred to as “in a specific way” in the first embodiment). The second embodiment discloses disposing the at least one correction element 12 on the light emitting element 11 by epitaxy, then wire bonding and encapsulating the at least one correction element 12 and the light emitting element 11 together (by top chip packaging), as shown in FIG. 4. The related equivalent circuit is shown in FIG. 5(B)

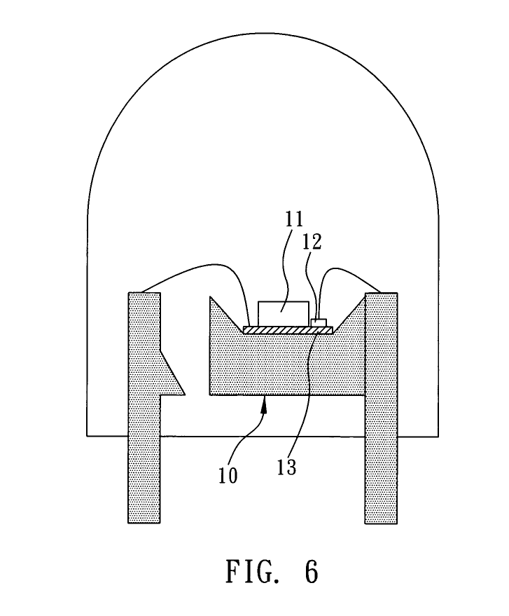

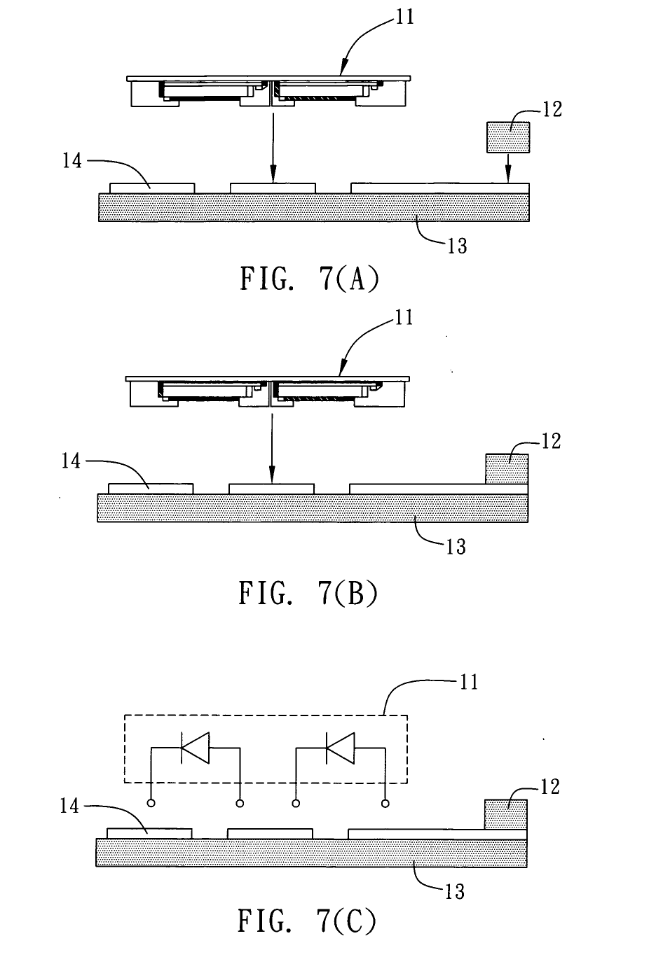

Referring to FIG. 6, which is a schematic view showing the structure of the third embodiment of a light emitting device of the present invention, the third embodiment is similar to the first and second embodiments in the way that not only does the light emitting device 1 comprise the carrying element 10, the light emitting element 11, and the at least one correction element 12, but the functions and implementation of the elements remain unchanged. Referring to the drawing, the third embodiment differs from the first and second embodiments in the way that the third embodiment further comprises a substrate 13 mounted with the light emitting element 11 (by flip-chip packaging). The third embodiment discloses electrically connecting the at least one correction element 12 (in a specific way) as shown in FIGS. 7(A) and 7(B).

Referring to FIG. 7(A), the at least one correction element 12 is integrally connected to the substrate 13, and then the at least one correction element 12, the substrate 13, and the light emitting element 11 are encapsulated together as shown in FIG. 6 (as shown in the drawing, a plurality of circuits 14 are formed on the substrate 13). Referring to FIG. 7(B), the at least one correction element 12 is fabricated on the substrate 13. Then, the at least one correction element 12, the substrate 13, and the light emitting element 11 are encapsulated together as shown in FIG. 4. The related equivalent circuit is shown in FIG. 7(C).

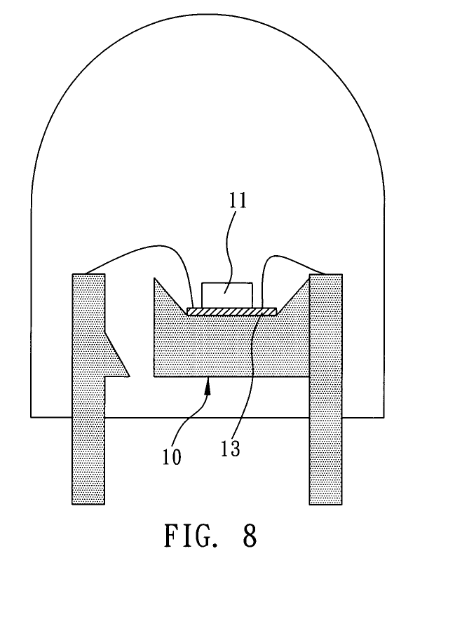

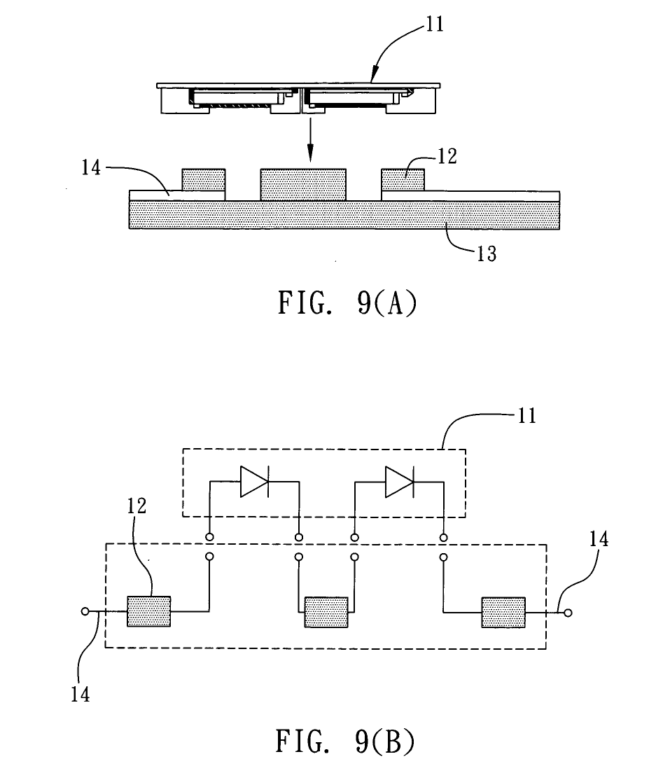

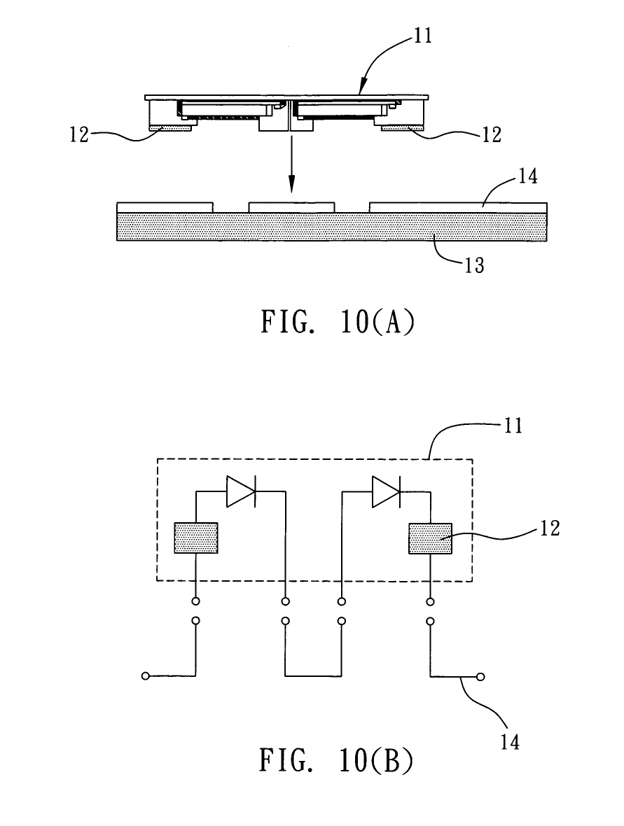

Referring to FIG. 8, which is a schematic view showing the structure of the fourth embodiment of a light emitting device of the present invention, the fourth embodiment is similar to the first, second and third embodiments in the way that not only does the light emitting device 1 comprise the carrying element 10, the light emitting element 11, and the at least one correction element 12, but the functions and implementation of the elements remain unchanged. Referring to the drawing, the fourth embodiment differs from the first, second and third embodiments in the way that the fourth embodiment not only comprises a substrate 13 mounted with the light emitting element 11 (by flip-chip packaging), but the electrical connection (referred to as “in a specific way”) of the at least one correction element 12 is new (as shown in FIGS. 9(A) and 10(A)).

Referring to FIG. 9(A), the at least one correction element 12 is disposed on the substrate 13 in the form of circuits 14. Then, the at least one correction element 12, the substrate 13, and the light emitting element 11 are encapsulated together as shown in FIG. 8. The equivalent circuit of FIG. 9(A) is shown in FIG. 9(B). Referring to FIG. 10(A), the at least one correction element 12 is disposed on the light emitting element 11 by epitaxy, and then the at least one correction element 12 and the light emitting element 11 are disposed on the substrate 13. Finally, the substrate 13, the at least one correction element 12, and the light emitting element 11 are encapsulated together as shown in FIG. 4. The equivalent circuit of FIG. 10(A) is shown in FIG. 10(B). An encapsulant for encapsulating all the aforesaid elements and components comprises metal or non-metal materials, such as ceramic, glass, resin, and transparent plastics.

As described above and shown in the drawings, the present invention discloses a light emitting device comprising a light emitting element and at least one correction element electrically connected to the light emitting element. Upon connection of the light emitting device with a power source, the light emitting element provides at least one function selected from the group consisting of temperature compensation, voltage correction, and surge absorption. Preferably, the light emitting element provides all the functions, namely temperature compensation, voltage correction, and surge absorption and thereby solves the following drawbacks of the prior art: current and power (which should otherwise be well-controlled and fall within a safe range) increase because of current-voltage shift resulting from a temperature change; and, with a relatively low yield of the dies for a light emitting element, the power sources (that is, the driving biases for the light emitting element) usually differ from one another, and in consequence light sources are seldom homogenous when operated under constant voltage. Advantages of the present invention are as follows: production yield increases, because dies of different biases can be fabricated and finished at the same level of production; and a light emitting device of the present invention is burn-resistant, because any pulse signal generated by instantaneous power supplied by a power source is readily absorbed (that is, power surge resistance).

The aforesaid embodiments merely serve as the preferred embodiments of the present invention. They should not be construed as to limit the scope of the present invention in any way. Hence, any other changes can actually be made in the present invention. It will be apparent to those skilled in the art that all equivalent modifications or changes made, without departing from the spirit and the technical concepts disclosed by the present invention, should fall within the scope of the appended claims.

What is claimed is:

1. A light emitting device, comprising:
a carrying element disposed with two electric conductors connectable to a power source;
a light emitting element disposed on the carrying element, electrically connected to the two electric conductors, and adapted to provide a light source upon connection of the two electric conductors with the power source; and
at least one correction element electrically connected to the light emitting element and adapted to provide the light emitting element with at least one function selected from the group consisting of temperature compensation, voltage correction, and surge absorption upon connection of the light emitting element with the power source.

2. The light emitting device of claim 1, wherein the carrying element is a carrier.

3. The light emitting device of claim 1, wherein the two electric conductors together form a lead frame.

4. The light emitting device of claim 1, wherein the light emitting element comprises a plurality of alternating current light emitting diode (AC LED) dies.

5. The light emitting device of claim 1, wherein the light emitting element comprises a plurality of direct current light emitting diode (DC LED) dies.

6. The light emitting device of claim 1, wherein the light emitting element is operable at a single wavelength.

7. The light emitting device of claim 1, wherein the light emitting element is operable at least two wavelengths.

8. The light emitting device of claim 1, wherein the light emitting element provides the light source comprising visible light upon connection to the power source.

9. The light emitting device of claim 1, wherein the light emitting element provides the light source comprising invisible light upon connection to the power source.

10. The light emitting device of claim 1, wherein the correction element is electrically connected to the light emitting element by a series connection.

11. The light emitting device of claim 1, wherein the correction element is electrically connected to the light emitting element by a parallel connection.

12. The light emitting device of claim 1, wherein the correction element is a temperature compensation element.

13. The light emitting device of claim 12, wherein the temperature compensation element is a positive temperature coefficient impedance compensation element.

14. The light emitting device of claim 12, wherein the temperature compensation element is a negative temperature coefficient impedance compensation element.

15. The light emitting device of claim 1, wherein the correction element is a voltage correction element.

16. The light emitting device of claim 15, wherein the voltage correction element can absorb voltage drop.

17. The light emitting device of claim 1, wherein the correction element is a surge absorption element.

18. The light emitting device of claim 1, wherein the correction element have at least two functions selected from the group consisting of temperature compensation, voltage correction, and surge absorption.

19. The light emitting device of claim 18, wherein the temperature compensation function is a positive temperature coefficient compensation function.

20. The light emitting device of claim 18, wherein the temperature compensation function is a negative temperature coefficient compensation function.

21. The light emitting device of claim 1, wherein the at least one correction element is electrically connected to the light emitting element in a specific way that involves integrally connecting the at least one correction element to a substrate then encapsulating the at least one correction element, the substrate and the light emitting element together.

22. The light emitting device of claim 1, wherein the at least one correction element is electrically connected to the light emitting element in a specific way that involves fabricating the at least one correction element on a substrate and then encapsulating the at least one correction element, the substrate and the light emitting element together.

23. The light emitting device of claim 1, wherein the at least one correction element is electrically connected to the light emitting element in a specific way that involves disposing the at least one correction element on a substrate in the form of circuits and then encapsulating the at least one correction element, the substrate and the light emitting element together.

24. The light emitting device of claim 1, wherein the at least one correction element is electrically connected to the light emitting element in a specific way that involves disposing the at least one correction element on the light emitting element by epitaxy and then encapsulating the at least one correction element and the light emitting element together.

25. The light emitting device of claim 1, wherein the at least one correction element is electrically connected to the light emitting element in a specific way that involves disposing the at least one correction element on the light emitting element by epitaxy, disposing the at least one correction element and the light emitting element on a substrate, and then encapsulating the at least one correction element, the light emitting element and the substrate together.
